(19) United States
(12) Patent Application Publication
(10) Pub. No.: US 2023/0025429 A1
(43) Pub. Date: Jan. 26, 2023

(54) METHOD FOR MANUFACTURING A SEMICONDUCTOR-ON-INSULATOR STRUCTURE FOR RADIOFREQUENCY APPLICATIONS

(71) Applicant: Soitec, Bemin (FR)

(72) Inventors: Aymen Ghorbel, Bernin (FR); Frédéric Allibert, Bernin (FR); Damien Massy, Bernin (FR); Isabelle Bertrand, Bernin (FR); Lamia Nouri, Bernin (FR)

(21) Appl. No.: 17/757,822

(22) PCT Filed: Jan. 7, 2021
(86) PCT No.: PCT/FR2021/050018

§ 371 Date: Jun. 21, 2022

(30) Foreign Application Priority Data
Jan. 7, 2020 (FR) FR2000098

(51) Int. Cl. H01L 21/761; H01L 21/762

(52) U.S. Cl. CPC H01L 21/761; H01L 21/76254

(57) ABSTRACT

The invention relates to a method for manufacturing a semiconductor-on-insulator structure (10), comprising the following steps: —providing an FD-SOI substrate (1) comprising, successively from its base to its top: a monocrystalline substrate (2) having an electrical resistivity of between 500 Ω·cm and 30 kΩ·cm, an interstitial oxygen content (Oi) of between 20 and 40 old ppma, and having an N- or P-type doping, an electrically insulating layer (3) having a thickness of between 20 nm and 400 nm, a monocrystalline layer (4) having a P-type doping, —heat-treating the FD-SOI substrate (1) at a temperature greater than or equal to 1175° C. for a time greater than or equal to 1 hour in order to form a P-N junction (5) in the substrate. The invention also relates to such a semiconductor-on-insulator structure.

### TECHNICAL FIELD OF THE INVENTION

The present invention relates to a method for manufacturing a semiconductor-on-insulator structure, in particular for radiofrequency applications. The invention also relates to a semiconductor-on-insulator structure obtained by implementing this method.

### PRIOR ART

Semiconductor-on-insulator structures are multilayer structures comprising a substrate that is generally made of silicon, an electrically insulating layer arranged on the substrate, which is generally an oxide layer such as a silicon oxide layer, and a semiconductor layer arranged on the insulating layer, which is generally a silicon layer.

Such structures are referred to as “Semiconductor-On-Insulator” structures (SeOI), in particular “Silicon-On-Insulator” (SOI) when the semiconductor material is silicon.

Among the existing SOI structures, the structures referred to as “Fully-Depleted Silicon-On-Insulator” (FD-SOI) structures are commonly used for digital applications. FD-SOI structures are characterized by the presence of a thin oxide layer, arranged on a silicon support substrate, and a very thin semiconductor layer arranged on the oxide layer, called SOI layer.

The oxide layer is located between the substrate and the SOI layer. The oxide layer is then referred to as “buried”, and is called “BOX” for “Buried OXide”.

The SOI layer allows the conduction channel of the FD-SOI structure to be implemented.

Due to the low thickness and the uniformity of the BOX layer and of the SOI layer, the conduction channel does not need to be doped, hence the structure can operate in a fully depleted mode.

FD-SOI structures have improved electrostatic features compared to structures without a BOX layer. The BOX layer decreases the parasitic electrical capacitance between the source and the drain, and also allows any electron leakage from the conduction channel to the substrate to be considerably reduced by confining the flow of electrons in the conduction channel, thereby reducing any electrical current losses and improving the performance capabilities of the structure.

FD-SOI structures can be compatible with radiofrequency (RF) applications, yet nevertheless suffer from the occurrence of electrical losses in said substrate.

In order to compensate for these electrical losses and to improve the RF performance capabilities, the use of a substrate is known, in particular of the SOI type, with high electrical resistivity, with this type of substrate commonly being called an “HR substrate” (High-Resistivity substrate). This HR substrate is advantageously combined with a charge-trapping layer (or “trap-rich layer”).

However, this type of substrate is not compatible with the use of transistors with a threshold voltage that must be controlled via a back-side gate (back-bias voltage). Indeed, the presence of this layer comprising trapped charges hinders back biasing (application of a potential difference to the back face).

The scientific publication entitled “Low loss Si-substrates enhanced using buried PN junctions for RF Applications” (M. Rack, L. Nyssens, and J-P. Raskin, IEEE Electron device letters, vol. 40, Issue 5) describes the formation of P-N junctions laterally arranged under the electrically insulating layer of a substrate intended for radiofrequency applications.

Laterally is understood to mean that two respectively P-doped and N-doped regions are arranged at the same depth of the substrate, with the junction between said regions being substantially perpendicular to the main surface of the substrate. Such a junction is obtained by implanting phosphorus over the whole substrate for N-type doping, followed by localized implantation of boron through a mask in order to form P-doped regions, then thermal treatment for activating the dopants.

Whilst a doped semiconductor is a good conductor, the junction hardly lets through any electrical current, thereby preventing the propagation of parasitic electric fields.

One disadvantage resulting from a lateral arrangement of the P-N junction as described in the scientific publication is that it requires a lithography step for forming the mask and two implantation steps, which represents a significant additional expense.

### BRIEF DESCRIPTION OF THE INVENTION

An aim of the invention is to propose a method for manufacturing a semiconductor-on-insulator structure that allows the aforementioned disadvantages to be overcome.

The aim of the invention is to propose such a manufacturing method for manufacturing an FD-SOI structure exhibiting good radiofrequency performance capabilities.

To this end, the invention proposes a method for manufacturing a semiconductor-on-insulator structure, comprising the following steps:
providing an FD-SOI substrate successively comprising, from its base to its top:
   a monocrystalline semiconductor substrate having electrical resistivity ranging between 500 Ω·cm and 30 Ω·cm, an interstitial oxygen content ranging between 20 and 40 old ppma, and having first P- or N-type doping;
   an electrically insulating layer having a thickness ranging between 20 nm and 400 nm;
   a monocrystalline semiconductive layer having P-type doping;
heat treating the FD-SOI substrate at a temperature greater than or equal to 1175° C. for a time greater than or equal to 1 hour, in order to form a P-N junction in the monocrystalline semiconductor substrate at a determined depth with respect to the electrically insulating layer,
   by diffusing P-type dopants from the monocrystalline semi-conductive layer through the electrically insulating layer in said substrate; and
   if the substrate is P-type doped, forming, in said substrate, heat donors by precipitation of the interstitial oxygen; and

in order to form, in the substrate, a first N-type doped region extending between the base of the substrate and the P-N junction and a second P-doped region located between the first region and the electrically insulating layer.

The main technique for measuring interstitial oxygen in the silicon of a semiconductor substrate is infrared absorption using Fourier Transform InfraRed (FTIR) spectrometry.

This FTIR measurement provides a value of an absorption coefficient α_{OX} due to the interstitial oxygen. The interstitial oxygen concentration is computed on the basis of this absorption coefficient α_{OX}, in accordance with the method that is particularly described in the document entitled “A Study of Oxygen Precipitation in Heavily Doped Silicon” (1989), Graupner, Robert Kurt, Dissertations and Theses, Paper 1218.

According to this method, the oxygen concentration as atoms per cm³ (at/cm³) or as a fraction of the total number of atoms present in parts per million (ppma) is obtained by multiplying the absorption coefficient α_{OX} by a conversion factor.

The oxygen concentration referred to in the invention (old ppma) is obtained by using the first of the four conversion factors presented in the following list, called “old ASTM” (American Society for Testing), expressed as ppma:
Old ASTM ppma=9.63α_{OX}
(ASTM F121-79) atoms/cm³=4.81×10¹⁷α_{OX}
New ASTM ppma=4.9α_{OX}
(ASTM F12143) atoms/cm³=2.45×10¹⁷α_{OX}
JEIDA ppma=6.1α_{OX}
   atoms/cm³=3.03×10¹⁷α_{OX}
IOC-88 ppma=6.28α_{OX}
   atoms/cm³=3.14×10¹⁷α_{OX}

According to other aspects, the manufacturing method of the invention has the different following features taken alone or according to their technically possible combinations:
the monocrystalline substrate is made of silicon and/or the monocrystalline layer is a silicon layer;
the FD-SOI substrate is obtained by transferring a layer of a donor substrate onto a recipient substrate, according to the following steps:
supplying:
   the donor substrate comprising a monocrystalline semiconductive layer having P-type doping, and an embrittlement zone located in the monocrystalline silicon layer defining the layer to be transferred; and
   the monocrystalline semiconductor recipient substrate, having electrical resistivity ranging between 500 Ω·cm and 30 kΩ·cm, an interstitial oxygen content ranging between 20 and 40 old ppma, and P- or N-type doping;
bonding the donor substrate onto the recipient substrate by means of an electrically insulating layer, the thickness of which ranges between 20 nm and 400 nm;
detaching the donor substrate along the embrittlement zone in order to form the FD-SOI substrate;
the FD-SOI substrate is obtained by transferring a layer of a donor substrate onto a recipient substrate, according to the following steps:
supplying:
   the donor substrate comprising a monocrystalline semiconductive layer having P-type doping; and
   the monocrystalline semiconductor recipient substrate, having electrical resistivity ranging between 500 Ω·cm and 30 Ω·cm, an interstitial oxygen content ranging between 20 and 40 old ppma, and P- or N-type doping;
bonding the donor substrate onto the recipient substrate by means of an electrically insulating layer, the thickness of which ranges between 20 nm and 400 nm;
thinning the donor substrate from the surface opposite the receiver substrate in order to form the transferred layer, so as to obtain the FD-SOI substrate;
the embrittlement zone is formed by implanting atomic species in the donor substrate so as to define the transfer layer;
the recipient substrate and the monocrystalline layer of the donor substrate are P-doped with boron:
the P-N junction is formed at a depth ranging between 1 μm and 5 μm from the electrically insulating layer,
the electrically insulating layer comprises a silicon oxide layer.

The invention also relates to a semiconductor-on-insulator structure obtained directly by implementing the previously described manufacturing method, wherein said semiconductor-on-insulator structure successively comprises, from its base to its top:
a monocrystalline semiconductor substrate having electrical resistivity ranging between 500 Ω·cm and 30 kΩ·cm, an interstitial oxygen content ranging between 20 and 40 old ppma, and comprising:
   a first region comprising N-type doping;
   a second region arranged on the first region, comprising P-type doping, the second region being separated from the first region by a P-N junction;
an electrically insulating layer;
a monocrystalline semiconductive layer comprising P-type doping.

According to other aspects, the structure of the invention has the different following features taken alone or according to their technically possible combinations:
the monocrystalline semiconductive layer is P-doped with boron;
the P-N junction is located at a depth ranging between 1 μm and 5 μm from the electrically insulating layer;
the electrically insulating layer comprises a silicon oxide layer;
the monocrystalline substrate is made of silicon and/or the monocrystalline layer is a silicon layer.

### DESCRIPTION OF THE FIGURES

Further advantages and features of the invention will become apparent upon reading the following description, which is provided by way of an illustrative and non-limiting example, with reference to the following appended figures, in which:

FIG. 1 is a diagram of an FD-SOI substrate;

FIG. 2 is a diagram of a semiconductor-on-insulator structure comprising a P-N junction, according to the invention;

FIG. 3 is a diagram that illustrates the inversion of the doping of a portion of the monocrystalline substrate with high electrical resistivity;

FIG. 4 is a diagram that illustrates the diffusion of the dopant from the monocrystalline layer through the underlying electrically insulating layer;

FIG. 5A is a diagram that illustrates the formation of an embrittlement zone by implanting atomic species in a donor substrate, according to a first embodiment;

FIG. 5B is a diagram that illustrates the bonding of the donor substrate onto a recipient substrate according to the first embodiment;

FIG. 5C is a diagram that illustrates the detachment of the donor substrate along the embrittlement zone, and the transfer of a layer from the donor substrate onto the recipient substrate, according to the first embodiment;

FIG. 6A is a diagram that illustrates the bonding of the donor substrate onto a recipient substrate according to a second embodiment;

FIG. 6B is a diagram that illustrates the thinning of the donor substrate from the surface opposite the recipient substrate in order to form the transferred layer;

FIG. 7 is a graph that illustrates the gain HD2 for a semiconductor-on-insulator structure with or without a P-N junction in the substrate with high electrical resistivity;

FIG. 8 is a graph that illustrates the gain S21 for a semiconductor-on-insulator structure with or without a P-N junction in the substrate with high electrical resistivity;

FIG. 9 is a graph that illustrates the resistivity of a semiconductor-on-insulator structure with or without a P-N junction in the substrate with high electrical resistivity.

### DETAILED DESCRIPTION OF EMBODIMENTS OF THE INVENTION

The invention relates to a method for manufacturing a semiconductor-on-insulator structure, as well as such a structure.

The manufacturing method of the invention allows semiconductor-on-insulator structures to be manufactured that comprise a P-N junction imparting good radiofrequency properties to said structure, and so doing in a simple and inexpensive manner.

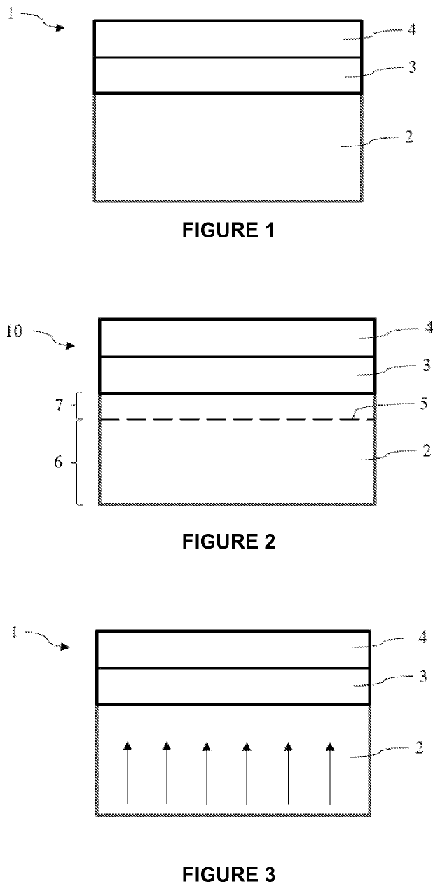

An FD-SOI substrate, schematically shown in FIG. 1 using reference sign 1, is initially provided, which substrate successively comprises, from its base to its top, a monocrystalline semiconductor substrate 2, an electrically insulating layer 3, and a monocrystalline semiconductive layer 4.

The monocrystalline substrate 2 is a substrate with high electrical resistivity, and thus has electrical resistivity ranging between 500 Ω·cm and 30 kΩ·cm.

In addition, the monocrystalline substrate 2 is a substrate with a high amount of oxygen, and thus has an interstitial oxygen content (Oi) ranging between 20 and 40 old ppma. The oxygen is trapped in the structure of the monocrystalline substrate, more specifically in the interstices located between the grains of the material forming the monocrystalline substrate, and is therefore called “interstitial oxygen”.

The monocrystalline substrate with high electrical resistivity and a high amount of interstitial oxygen is also referred to as an HR HiOi (which is a combination of the acronyms for “High Resistivity” and “High Oxygen”) substrate.

Preferably, the monocrystalline substrate is made of silicon.

The monocrystalline substrate has P- or N-type doping.

In the case of N-type doping, the monocrystalline substrate 2 is preferably doped with phosphorus, and, more preferably, the monocrystalline substrate is made of phosphorus-doped silicon.

In the case of P-type doping, the monocrystalline substrate 2 is preferably doped with boron, and, more preferably, the monocrystalline substrate is made of boron-doped silicon.

The thickness of the electrically insulating layer 3, also referred to as a BOX layer in that it is arranged between the underlying monocrystalline substrate 2 and the overlying monocrystalline layer 4, ranges between 20 nm and 400 nm.

Preferably, the electrically insulating layer 3 comprises a silicon oxide layer.

The monocrystalline layer 3 has P-type doping.

Preferably, the monocrystalline layer is a silicon layer.

According to the method of the invention, a heat treatment is applied to the FD-SOI substrate at a temperature greater than or equal to 1175° C., for a time greater than or equal to 1 hour.

During said heat treatment, a P-N junction, reference sign 5, is formed in the monocrystalline substrate 2 at a determined depth with respect to the electrically insulating layer 3, as illustrated in FIG. 2.

More specifically, the heat treatment causes the following phenomena.

On the one hand, P-type dopants of the monocrystalline layer diffuse into the monocrystalline substrate through the electrically insulating layer, in a region of the substrate neighboring the electrically insulating layer.

On the other hand, when the monocrystalline substrate is P-doped, the type of doping in the monocrystalline substrate 2 is inverted.

Combining these two phenomena produces a region 6, called first region, in the substrate, which region extends from the base of the monocrystalline substrate to the P-N junction and which is N-type doped due to the inversion of the type of doping. The P-N junction then marks the boundary between the first region 6, and the remaining region 7, called the second region, of the monocrystalline substrate, which region extends from the P-N junction to the electrically insulating layer 3 and which remains P-doped, with the diffusion of the P-type dopants in this second region having compensated for the inversion of the type of doping.

When the monocrystalline substrate is N-doped, the aforementioned phenomenon of diffusing P-type dopants in the second region occurs. However, the phenomenon of inverting the type of doping does not occur. Consequently, the first region remains N-type doped.

Irrespective of the initial type of doping of the monocrystalline substrate, on completion of the heat treatment, the monocrystalline substrate comprises a P-N junction separating the first N-type doped region (located next to the base of the substrate) and the second P-type doped region (located next to the electrically insulating layer).

The P-N junction can be formed due to the following three features:
P doping of the monocrystalline layer 4;
the temperature of the heat treatment greater than or equal to 1175° C., for a time greater than or equal to 1 hour; and
in the case of a P-type doped monocrystalline substrate, the high interstitial oxygen concentration of said monocrystalline substrate 2.

The presence of the P-N junction associated with the high electrical resistivity of the crystalline substrate 2, ranging between 500 Ω·cm and 30 kΩ·cm, allows a structure to be obtained that exhibits very good radiofrequency properties. These properties will be illustrated throughout the remainder of the present document. Adjusting these three features allows the formation of the P-N junction to be controlled, and in particular its depth in the monocrystalline substrate 2 from the electrically insulating layer 3.

The parameters of the method, such as, for example, the three aforementioned features, are adjusted so as to form the P-N junction at a depth ranging between 1 μm and 5 μm from the electrically insulating layer.

In the case of a P-type monocrystalline substrate, the heat treatment causes the interstitial oxygen present in the monocrystalline substrate 2 to precipitate, which forms sulfur oxide SₓO_{y} heat donors provided with surplus charges for doping the material of the monocrystalline substrate, and thereby reversing the doping thereof. This first phenomenon is schematically shown in FIG. 3, which shows the doping of the material of the monocrystalline substrate by the heat donors using the upward vertical arrows 8.

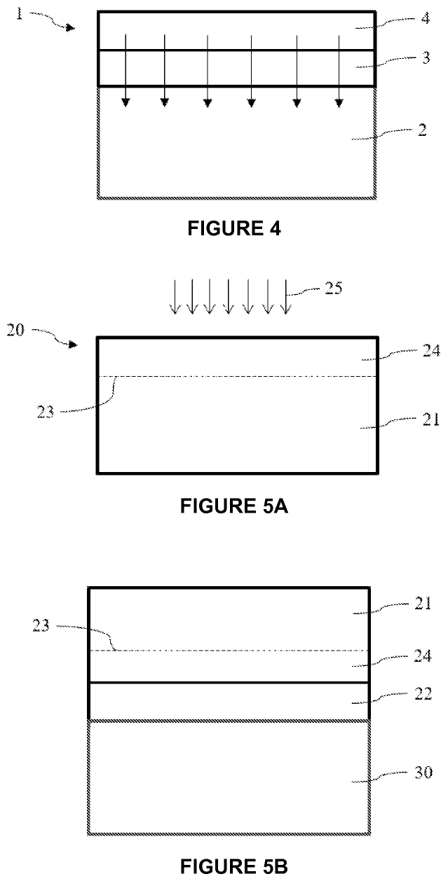

Furthermore, whether or not the monocrystalline substrate is N- or P-type doped, the heat treatment causes the dopants of the monocrystalline layer 4, such as boron, to diffuse through the electrically insulating layer 3, which is thin enough, into the monocrystalline substrate 2. These dopants also can be used to control the formation of the P-N junction, and in particular its depth in the monocrystalline substrate from the electrically insulating layer. This second phenomenon is schematically shown in FIG. 4, which shows the diffusion of the dopants through the electrically insulating layer using the downward vertical arrows 9.

This second phenomenon, combined with the first in the case of a P-type doped monocrystalline substrate, lead to the formation of the first region of the N-doping substrate, and to the formation of the second P-doped region, located between the first region and the electrically insulating layer, shown on the semiconductor-on-insulator structure 10 of FIG. 2.

The method of the invention offers the advantage of allowing these two phenomena to occur by virtue of the three previously listed features, without needing additional processing steps. In particular, unlike the lateral P-N junction described in the aforementioned article by M. Rack et al., forming the P-N junction in the thickness of the substrate in the present invention does not require any localized implantation of dopants or any mask to be deposited on the substrate.

According to a preferred embodiment, the FD-SOI substrate is obtained by transferring a layer of a donor substrate onto a recipient substrate.

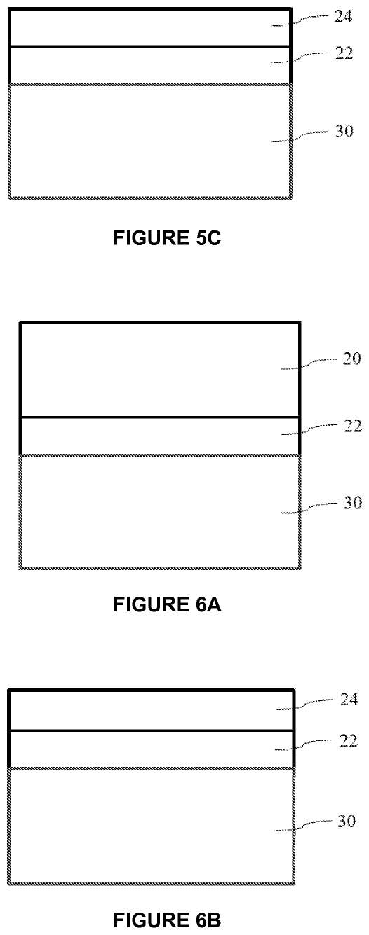

According to a first alternative of this embodiment illustrated in FIGS. 5A, 5B, and 5C, a donor substrate 20 is provided comprising a monocrystalline layer 21, preferably a silicon layer, with N-type doping, and an embrittlement zone 23 located in the monocrystalline layer 24 defining the layer to be transferred, as illustrated in FIG. 5A.

The monocrystalline layer 24 to be transferred preferably is a silicon layer.

A monocrystalline recipient substrate 30, preferably made of silicon, is also provided with electrical resistivity ranging between 500 Ω·cm and 30 kΩ·cm, an interstitial oxygen content (Oi) ranging between 20 and 40 old ppma, and P- or N-type doping.

With reference to FIG. 5B, the donor substrate 20 is then bonded onto the recipient substrate 30 by means of an electrically insulating layer 22, the thickness of which ranges between 20 nm and 400 nm. The electrically insulating layer 22 is then located between the donor substrate 20 and the recipient substrate 30.

The electrically insulating layer 22 can originate from the donor substrate or from the recipient substrate, i.e., it initially can be located on the donor substrate or on the receiver substrate prior to bonding.

With reference to FIG. 5C, the donor substrate 20 is then detached along the embrittlement zone 23 in order to obtain the FD-SOI substrate.

Preferably, the layer 24 is transferred from the donor substrate 20 to the recipient substrate 30 in accordance with the Smart Cut™ method, in which the embrittlement zone 23 is formed by implanting atomic species such as, for example, hydrogen and/or helium atoms, in the donor substrate, then the donor substrate is detached along said embrittlement zone.

According to a second alternative of this embodiment illustrated in FIGS. 6A and 6B, a donor substrate 20 is provided comprising a monocrystalline semiconductive layer 21, preferably a silicon layer, with P-type doping.

The monocrystalline layer 21 preferably is a silicon layer.

A monocrystalline recipient substrate 30, preferably made of silicon, is also provided with electrical resistivity ranging between 500 Ω·cm and 30 Ω·cm, an interstitial oxygen content (O) ranging between 20 and 40 old ppma, and P- or N-type doping.

With reference to FIG. 6A, the donor substrate 20 is then bonded onto the recipient substrate 30 by means of an electrically insulating layer 22, the thickness of which ranges between 20 nm and 400 nm. The electrically insulating layer 22 is then located between the donor substrate 20 and the recipient substrate 30.

The electrically insulating layer 22 can originate from the donor substrate or from the recipient substrate, i.e., it initially can be located on the donor substrate or on the receiver substrate prior to bonding.

With reference to FIG. 6B, the donor substrate 20 is then thinned from the surface opposite the receiver substrate in order to form the transferred layer 24, in order to obtain the FD-SOI substrate 1.

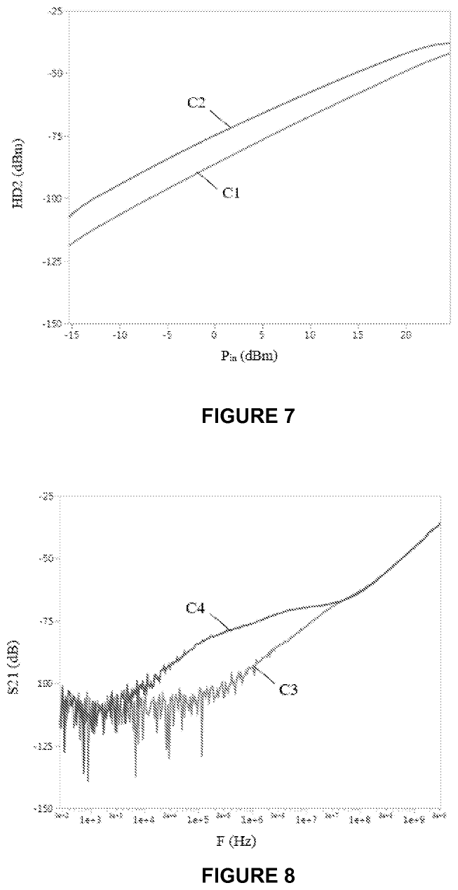

The good radiofrequency properties of the semiconductor-on-insulator structure obtained by the previously described method are illustrated with reference to FIGS. 7, 8, and 9.

FIG. 7 is a graph that illustrates the gain HD2 (dBm) for a semiconductor-on-insulator structure with or without a P-N junction in the substrate with high electrical resistivity.

The gain HD2 corresponds to the second harmonic, measured at a frequency of 900 Mhz.

More specifically, HD2 is the harmonic generated by the substrate capable of interfering with the operation of a radiofrequency device comprising the structure according to the invention. The weaker the HD2, the more insulating the substrate. The HD2 is measured across a coplanar line with an input point and an output point. At the input point, a power Pᵢₙ(dBm) is imposed, and at the output the power Pₒᵤₜ is measured, which is broken down into several harmonics, in particular including HD1, which corresponds to the power measured at the output that is approximately equal to the input power, and HD2, which corresponds to the harmonic generated by the substrate.

According to the graph of FIG. 7, the gain HD2 obtained for the structure comprising a P-N junction (curve C1) is less than that obtained for a structure without a P-N junction (curve C2). This downward offset of the curve C2 with respect to the curve C1 corresponds to a loss of approximately 10 dBm.

For this reason, the high resistivity substrate of the structure with a P-N junction is more electrically insulating than that of the structure without a P-N junction.

FIG. 8 is a graph that illustrates the gain S21 (dB) for a semiconductor-on-insulator structure with or without a P-N junction, as a function of the frequency (Hz).

The gain S21 corresponds to a cross-talk or noise measurement (called “cross-talk”) that reflects the ability of any components compared to other components to communicate through the substrate, thus representing the insulation performance capability of the substrate.

According to the graph of FIG. 8, a reduction is observed in the gain S21 obtained for the structure comprising a P-N junction (curve C3) compared to that obtained for a junction without a P-N structure (curve C4), between 1e+3 Hz and 1e+8 Hz. This reduction in the curve C4 compared to the curve C3 corresponds to a reduced noise.

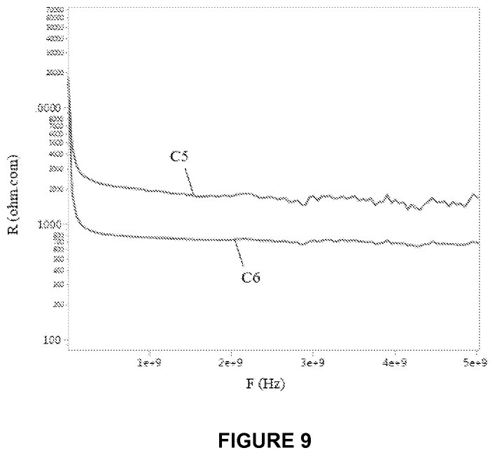

FIG. 9 is a graph that illustrates the resistivity R (ohm·cm) of a semiconductor-on-insulator structure with or without a P-N junction in the substrate with high electrical resistivity, as a function of the frequency (Hz).

According to the graph of FIG. 9, the resistivity obtained for the structure comprising a P-N junction (C5 curve) is greater than that obtained for a structure without a P-N junction (curve C6). This downward offset of the curve C5 compared to the curve C6 corresponds to a loss of approximately 1200 ohm·cm.

This confirms the fact that the substrate with high resistivity of the structure with a P-N junction is more electrically insulating than that of the structure without a P-N junction.

The graphs of FIGS. 7, 8, and 9 thus show that the radiofrequency performance capabilities of the semiconductor-on-insulator structure of the invention, comprising a P-N junction, are significantly improved compared to those of a structure without a P-N junction.

1. A method for manufacturing a semiconductor-on-insulator structure (10), comprising the following steps:
providing an FD-SOI substrate (1) successively comprising, from its base to its top:
a monocrystalline semiconductor substrate (2) having electrical resistivity ranging between 500 Ω·cm and 30 kΩ·cm, an interstitial oxygen content (Oi) ranging between 20 and 40 old ppma, and having first P- or N-type doping;
an electrically insulating layer (3) having a thickness ranging between 20 nm and 400 nm;
a monocrystalline semiconductive layer (4) having P-type doping;
heat treating the FD-SOI substrate (1) at a temperature greater than or equal to 1175° C. for a time greater than or equal to 1 hour, in order to form a P-N junction (5) in the monocrystalline semiconductor substrate (2) at a determined depth with respect to the electrically insulating layer (3),
by diffusing P-type dopants from the monocrystalline semi-conductive layer (4) through the electrically insulating layer (3) in said substrate; and
if the substrate (2) has P-type doping, forming, in said substrate (2), heat donors by precipitation of the interstitial oxygen:
in order to form, in the substrate, a first region (6) having N-type doping extending between the base of the substrate and the P-N junction and a second P-doped region (7) located between the first region (6) and the electrically insulating layer (3).

2. The manufacturing method as claimed in claim 1, wherein the monocrystalline substrate (2) is made of silicon and/or the monocrystalline layer (4) is a silicon layer.

3. The manufacturing method as claimed in claim 1 or claim 2, wherein the FD-SOI substrate (1) is obtained by transferring a layer (24) of a donor substrate (20) onto a recipient substrate (30), according to the following steps:
supplying:
the donor substrate (20) comprising a monocrystalline semiconductive layer (21) having P-type doping, and an embrittlement zone (23) located in the monocrystalline silicon layer (21) defining the layer (24) to be transferred; and
the monocrystalline semiconductor recipient substrate (30) having electrical resistivity ranging between 500 Ω·cm and 30 k Ω·cm, an interstitial oxygen content (O) ranging between 20 and 40 old ppma, and first P- or N-type doping;
bonding the donor substrate (20) onto the recipient substrate (30) by means of an electrically insulating layer (22), the thickness of which ranges between 20 nm and 400 nm;
detaching the donor substrate (20) along the embrittlement zone (23) in order to form the FD-SOI substrate (1).

4. The manufacturing method as claimed in claim 1 or claim 2, wherein the FD-SOI substrate (1) is obtained by transferring a layer (24) of a donor substrate (20) onto a recipient substrate (30), according to the following steps:
supplying:
the donor substrate (20) comprising a monocrystalline semiconductive layer (21) having P-type doping; and
the monocrystalline semiconductor recipient substrate (30) having electrical resistivity ranging between 500 Ω·cm and 30 Ω·cm, an interstitial oxygen content (Oi) ranging between 20 and 40 old ppma, and P- or N-type doping;
bonding the donor substrate (20) onto the recipient substrate (30) by means of an electrically insulating layer (22), the thickness of which ranges between 20 nm and 400 nm;
thinning the donor substrate (20) from the surface opposite the receiver substrate (30) in order to form the transferred layer (24), so as to obtain the FD-SOI substrate (1).

5. The method as claimed in claim 3, wherein the embrittlement zone (24) is formed by implanting atomic species in the donor substrate (20) so as to define the transfer layer (24).

6. The method as claimed in any one of claims 3 to 5, wherein the recipient substrate (30) and the monocrystalline layer (21) of the donor substrate are P-doped with boron.

7. The method as claimed in any one of the preceding claims, wherein the P-N junction (5) is formed at a depth ranging between 1 μm and 5 μm from the electrically insulating layer (3).

8. The method as claimed in any one of the preceding claims, wherein the electrically insulating layer (3) comprises a silicon oxide layer.

9. A semiconductor-on-insulator structure (10) obtained directly by implementing the manufacturing method as claimed in any one of the preceding claims, wherein said semiconductor-on-insulator structure (10) successively comprises, from its base to its top:
a monocrystalline semiconductor substrate (2) having electrical resistivity ranging between 500 Ω·cm and 30 k Ω·cm, an interstitial oxygen content (Oi) ranging between 20 and 40 old ppma, and comprising:
a first region (6) comprising N-type doping; and
a second region (7) arranged on the first region, comprising P-type doping, the second region (7) being separated from the first region (6) by a P-N junction (5);
an electrically insulating layer (3);
a monocrystalline semiconductive layer (4) comprising P-type doping.

10. The semiconductor-on-insulator structure (10) as claimed in claim 9, wherein the monocrystalline semiconductive layer (4) is P-doped with boron.

11. The semiconductor-on-insulator structure (10) as claimed in claim 9 or claim 10, wherein the P-N junction (5) is located at a depth ranging between 1 μm and 5 μm from the electrically insulating layer (3).

12. The semiconductor-on-insulator structure (10) as claimed in any one of claims 9 to 11, wherein the electrically insulating layer (3) comprises a silicon oxide layer.

13. The semiconductor-on-insulator structure (10) as claimed in any one of claims 9 to 12, wherein the monocrystalline substrate (2) is made of silicon and/or the monocrystalline layer (4) is a silicon layer.
